(19) United States
(12) Patent Application Publication
(10) Pub. No.: US 2011/0109830 A1
(43) Pub. Date: May 12, 2011

(54) BACK COVER MODULE AND ASSEMBLING METHOD THEREOF, BACKLIGHT MODULE AND ASSEMBLING METHOD THEREOF, AND FLAT PANEL DISPLAY DEVICE AND ASSEMBLING METHOD THEREOF

(75) Inventors: Chung-min Wang, Hsin-Chu City (TW); Wei-chen Yu, Hsin-Chu City (TW)

(73) Assignee: AU Optronics Corp., Hsin-Chu (TW)

(21) Appl. No.: 12/764,096

(22) Filed: Apr. 21, 2010

(30) Foreign Application Priority Data
Nov. 6, 2009 (TW) 098137850

(51) Int. Cl. G02F 1/1333; H05K 5/03; G09F 13/04

(52) U.S. Cl. 349/58; 361/679.01; 362/97.1

(57) ABSTRACT

A back cover module and assembling method thereof, a backlight module and assembling method thereof, and a flat panel display device and assembling method thereof are disclosed. The flat panel display device includes the backlight module and a display panel disposed on the backlight module. The backlight module includes the back cover module, a reflector disposed on an inner surface of a back cover body of the back cover module, and a light source module disposed on the reflector. The back cover module includes the back cover body, a first U-shaped plastic frame, and a second U-shaped plastic frame. The first and second U-shaped plastic frames are fixed at four corners of the back cover body. By the present invention, a size of the back cover body can be reduced so as to achieve objectives of decreasing cost and weight of the flat panel display device.

### CLAIM OF PRIORITY

This application claims priority to Taiwanese Patent Application No. 098137850 filed on Nov. 6, 2009.

### BACKGROUND OF THE INVENTION

1. Field of the Invention

The present invention relates to a back cover module, a backlight module, and a flat panel display device and more particularly, to a back cover module and the assembling method thereof, a backlight module and the assembling method thereof, and a flat panel display device and the assembling method thereof which are able to lower costs, reduce weight, and increase strength.

2. Description of the Prior Art

Referring to FIG. 1, an exploded diagram is shown illustrating a conventional flat panel display device 1. The flat panel display device 1 sequentially comprises a back cover 10, a reflector 12, a light source module 14, a set of left and right plastic strips 16, a set of optical films 18, a set of top and bottom plastic strips 20, a display panel 22, and a front cover 24.

The back cover 10, acting as a base or substrate of the flat panel display device 1, is usually a sheet which is made of metallic material such as iron and the like. When the above-mentioned elements are assembled, the sequential steps are as follows: The reflector 12 is stuck onto the back cover 10; the light source module 14 is fixed onto the reflector 12 with the set of left and right plastic strips 16; the set of optical films 18 are clipped between the set of left and right plastic strips 16 with the set of top and bottom plastic strips 20; then, the display panel 22 is assembled; finally, the above-mentioned elements are fixed onto the back cover 10 with the front cover 24.

However, the metallic back cover 10, which supports all of the elements, is usually designed to be slightly larger in size than the reflector 12, so relatively higher manufacturing costs are required. Moreover, because the back cover 10 is made of a metallic material such as iron, it weighs more heavily. After the flat panel display device 1 finishes being assembled, it is difficult in making delivery.

Therefore, it is necessary to propose another method to solve the above-mentioned problems.

### SUMMARY OF THE INVENTION

In order to solve the problems occurring in the prior art, one object of the present invention is to provide a back cover module and the assembling method thereof, a backlight module and the assembling method thereof, and a flat panel display device and the assembling method thereof which can lower manufacturing costs and reduce weight and meanwhile, take strength into consideration.

According to present invention, a flat panel display device comprises a backlight module and a display panel disposed on the backlight module. The backlight module comprises a back cover body, a reflector disposed on an inner surface of the back cover body, and a light source module disposed on the reflector positioned between the back cover module and the light source module. The back cover module comprises a back cover body, a first U-shaped plastic frame, and a second U-shaped plastic frame. The back cover body comprises a first corner, a second corner, a third corner, and a fourth corner. The first U-shaped plastic frame comprises a first end fixed on the first corner and a second end fixed on the second corner. The second U-shaped plastic frame comprises a third end fixed on the third corner and a fourth end fixed on the fourth corner. The light source module is positioned between the back cover body and the display panel.

According to present invention, a method of assembling a flat panel display device comprises the steps of:

providing a back cover body, a first U-shaped plastic frame, and a second U-shaped plastic frame, wherein the back cover body comprises a first corner, a second corner, a third corner, a fourth corner, and a first sliding track formed between the first corner and the third corner, the first U-shaped plastic frame comprises a first end and a second end, and the second U-shaped plastic frame comprises a third end and a fourth end, the first sliding track accommodating the first end and the third end;

fixing the first end of the first U-shaped plastic frame on the first corner and fixing the second end of the first U-shaped plastic frame on the second corner;

fixing the third end of the second U-shaped plastic frame on the third corner and fixing the fourth end of the second U-shaped plastic frame on the fourth corner;

positioning a reflector on an inner surface of the back cover body;

positioning a light source module on the reflector, so that the reflector is positioned between the back cover module and the light source module; and

positioning a display panel disposed on the backlight module, wherein the light source module is positioned between the back cover body and the display panel.

Comparing with the prior art, the present invention adopts a back cover module as a substrate module and utilizes the back cover body, the first U-shaped plastic frame, and the second U-shaped plastic frame to form a supporting structure. Hence, the size of the back cover body can be reduced, and the manufacturing costs and the weight of the flat panel display device can be lowered as well.

The present invention will be described with reference to the accompanying drawings, which show exemplary embodiments of the present invention.

### BRIEF DESCRIPTION OF THE DRAWINGS

FIG. 1 depicts an exploded diagram is shown illustrating a conventional flat panel display device.

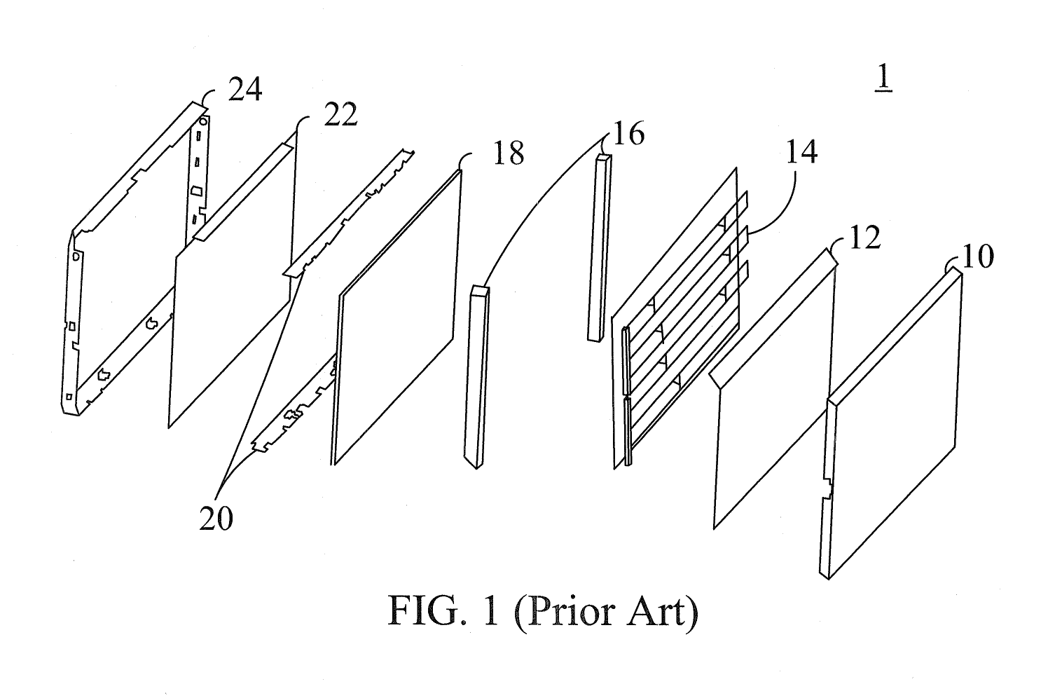

FIG. 2 illustrates an exploded diagram of a flat panel display device according to a first embodiment of the present invention.

FIG. 3 illustrates an enlarged diagram of the back cover module of FIG. 2.

FIG. 4 illustrates a back cover module according to a second embodiment of the present invention.

FIG. 5 illustrates a back cover module according to the third embodiment of the present invention.

FIG. 6 illustrates the back cover module of FIG. 5 (or the back cover module of FIG. 4 or the back cover module of FIG. 3) where the light source module and the reflector are fixed.

FIGS. 7A and 7B illustrate that a lamp holder of the backlight module is installed onto the first base plate of the first U-shaped plastic frame.

FIGS. 8A and 8B illustrates that a first electrode holder and a second electrode holder of the backlight module are installed onto the second base plate of the second U-shaped plastic frame.

FIG. 9 shows PCBs for use in the flat panel display device of the present invention.

FIG. 10 illustrates the source board and the back cover body.

FIG. 11A and FIG. 11B show how to assemble the LIPS board and the back cover body.

FIG. 12 illustrates the main board according to another embodiment.

### DETAILED DESCRIPTION OF THE INVENTION

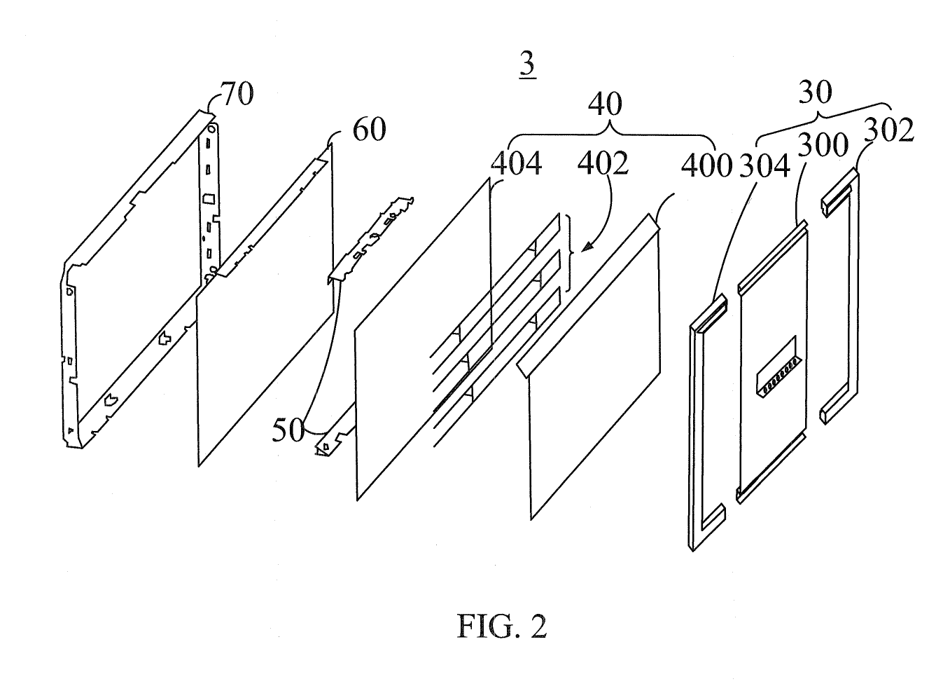

Referring to FIG. 2 illustrating an exploded diagram of a flat panel display device 3 according to a first embodiment of the present invention, the flat panel display device 3 comprises a back cover module 30, a backlight module 40, a set of top and bottom plastic strips 50, a display panel 60, and a front cover 70.

The back cover module 30 comprises a back cover body 300, a first U-shaped plastic frame 302, and a second U-shaped plastic frame 304. The backlight module 40 comprises a reflector 400, a light source module 402, and a set of optical films 404. During the process of assembling all of the elements, the reflector 400 is disposed on the inner surface of the back cover body 300, and the light source module 402 is disposed on the reflector 400; that is, the reflector 400 is positioned between the back cover module 30 and the light source module 402. The set of top and bottom plastic strips 50 are utilized to fix the set of optical films 404 onto the reflector 400 and the light source module 402. The display panel 60 is disposed on the backlight module 40, and the light source module 402 is positioned between the back cover body 300 and the display panel 60. The front cover 70 is utilized to fix the backlight module 40, the set of top and bottom plastic strips 50, and the display panel 60 onto the back cover module 30.

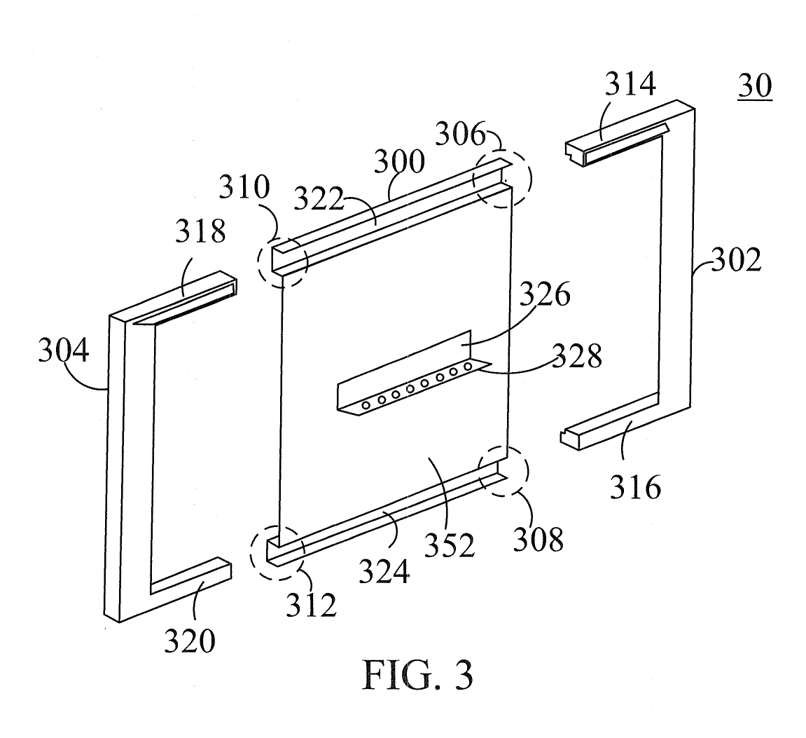

Referring to FIG. 3 illustrating an enlarged diagram of the back cover module 30 of FIG. 2, the back cover body 300 is made of a metallic material such as aluminum, iron, stainless steel, and so on. The top and bottom edges of the back cover body 300 comprise a first sliding track 322 and a second sliding track 324, respectively. The profile of the sliding tracks 322 and 324 can be U-shaped. The base of the U-shape sliding tracks 322 and 324 fronts onto the inner or outer side of the back cover module 30, and correspondingly, the opening of the U-shape fronts onto the inner or outer side of the back cover module 30. The opposite ends of the first sliding track 322 comprise a first corner 306 and a third corner 310; the opposite ends of the second sliding track 324 comprise a second corner 308 and a fourth corner 312. The first U-shaped plastic frame 302 comprises a first end 314 and a second end 316; the second U-shaped plastic frame 304 comprises a third end 318 and a fourth end 320. When the back cover module 30 is assembled, the first end 314 and the third end 318 enter and are partially placed in the first sliding track 322 through the first corner 306 and the third corner 310, respectively, and the second end 316 and the fourth end 320 enter and are partially placed in the second sliding track 324 through the second corner 308 and the fourth corner 312, respectively. Afterwards, the first end 314 is fixed onto the first corner 306, the second end 316 is fixed onto the second corner 308, the third end 318 is fixed onto the third corner 310, and the fourth end 320 is fixed onto the fourth corner 312 with bolts or screws or by way of glue joining, lodging, or other methods of fixation.

An opening space is enclosed and formed between the first U-shaped plastic frame 302 and the back cover body 300, and another opening space is formed between the second U-shaped plastic frame 304 and the back cover body 300. Thus, an amount of material used to manufacture the first U-shaped plastic frame 302, the back cover body 300, and the second U-shaped plastic frame 304 is reduced, which lowers the overall weight and saves costs. Moreover, vents are thus formed as well, which enhances the heat dissipation effect. In this embodiment, preferably, the length of two arms with the first end 314 and the second end 316 of the first U-shaped plastic frame 302 is about one-third to one-half the width of the back cover body 300; and/or the length of two arms with the third end 318 and the fourth end 320 of the second U-shaped plastic frame 304 is about one-third to one-half the width of the back cover body 300. However, it is to be understood that the length of the arms of the plastic frames 302 and 304 is not limited to above-mentioned range.

Approximately in the middle of the back cover body 300, an opening 326 and a bearing plate 328 are additionally stamped. The bearing plate 328 connects the edge of the opening 326 and protrudes out of the outer surface 352 of the back cover body 300. In another embodiment, an added bearing plate 328 is fixed onto the opening 326 and protrudes out of the outer surface 352 of the back cover body 300.

As shown in FIG. 2 and FIG. 3, the back cover module 30 of the flat panel display device 3 acts as a substrate module; the back cover body 300, the first U-shaped plastic frame 302, and the second U-shaped plastic frame 304 are comprised a supporting structure. As a result, the back cover body 300 is reduced in size while still maintaining the overall strength, which lowers the manufacturing costs and the weight.

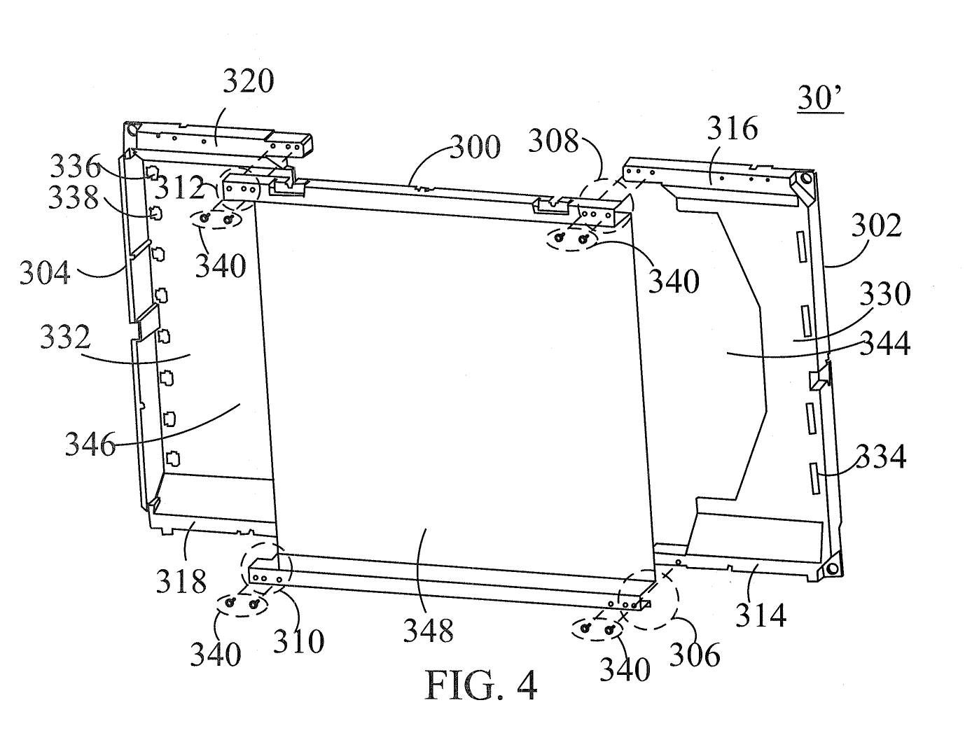

Referring to FIG. 4 illustrating a back cover module 30′ according to a second embodiment of the present invention, the first U-shaped plastic frame 302 of the second embodiment comprises a first base plate 330, and the second U-shaped plastic frame 304 additionally comprises a second base plate 332. The first base plate 330 additionally comprises a gap 344 disposed between the first end 314 and the second end 316 and corresponds to one side of the back cover body 300 comprising the first corner 306 and the second corner 308. The first U-shaped plastic frame 302 comprises two arms with the first end 314 and the second end 316, the length of which is about one-third to one-half the width of the back cover body 300. And/Or the second U-shaped plastic frame 304 comprises two arms with the third end 318 and the fourth end 320, the length of which is about one-third to one-half the width of the back cover body 300. However, it is to be understood that the length of the arms of the plastic frames 302 and 304 is not limited to above-mentioned range. In this embodiment, an opening space is formed only between the first U-shaped plastic frame 302 and the back cover body 300, and a closed space is formed between the second U-shaped plastic frame 304 and the back cover body 300.

In general, no other elements, such as printed circuit boards (PCBs), are disposed on the first base plate 330. As a result, the object of the gap 344 is to reduce the usage area of the first base plate 330 to lower the overall weight and to save costs, as well as to form a vent to enhance the heat dissipation effect. The second base plate 332, adjacent to a lateral edge of the back cover body 300, are flush with the lateral edge of the back cover body 300 or is separated from the lateral edge of the back cover body 300 by a slight distance. In this embodiment, the first end 314, the second end 316, the third end 318, and the fourth end 320 are respectively fixed onto the first corner 306, the second corner 308, the third corner 310, and the fourth corner 312 of the back cover body 300 by using added fixation elements such as bolts and screws 340 or furthermore, by adopting other methods of fixation such as engaging. The other elements are the same as those of the first embodiment, so no further details are described here. When the flat panel display device 3 finishes being assembled, the reflector 400 (as shown in FIG. 2) covers the inner surfaces of the first base plate 330, the back cover body 300, and the second base plate 332. The first base plate 330 and the inner surface 346 of the second base plate 332 are coplanar with the inner surface 348 of the back cover body 300. It is more particularly described as follows: Other elements such as PCBs are usually disposed on the outer surface 354 or inner surface 346 of the second base plate 332. In order to comply with regulations, the second base plate 332 must be made of water-proof materials and cannot comprise any gaps like the gap 344 of the first base plate 330. The opening 326 and the bearing plate 328 described in the first embodiment can be disposed in the second embodiment as well.

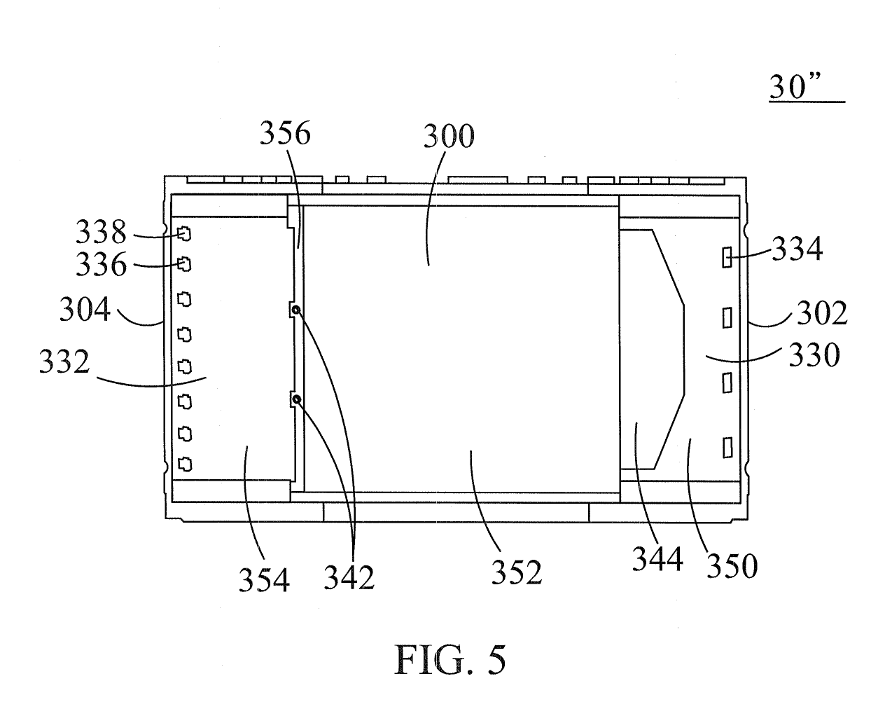

Referring to FIG. 5 illustrating a back cover module 30″ according to the third embodiment of the present invention, the first U-shaped plastic frame 302 and the second U-shaped plastic frame 304 are fixed onto the outer surface 352 or inner surface 348 of the back cover body 300 with the screws 340 (as shown in FIG. 4); in addition, the junction of the outer surface 354 of the second base plate 332 and the outer surface 352 of the back cover body 300 can be locked with screws 342 or through other methods of fixation so as to enhance the stability of the outer surface 354 and the outer surface 352. The other elements are the same as those of the second embodiment, so no further details are provided. A large proportion of the outer surface 350 of the first base plate 330 are roughly coplanar with the outer surface 352 of the back cover body 300. The back cover body 300, adjacent to a lateral edge of the first base plate 330, partially covers the lateral edge of the back cover body 300 and the first base plate 330, especially the lateral edges of the top and bottom of the gap 344. In this embodiment, a large proportion of the outer surface 354 of the second base plate 332 are roughly coplanar with the outer surface 352 of the back cover body 300. However, the lateral edge between the second base plate 332 and the back cover body 300 comprises a slight bending 356 where the screws 342 or other methods of fixation are utilized to fix the lateral edge between the second base plate 332 and the back cover body 300. It is more particularly described as follows: The outer surface 354 of the second base plate 332 can form a non-coplanar structure with the outer surface 352 of the back cover body 300 as long as the second base plate 332 is coplanar with the inner surface 348 of the back cover body 300 (as shown in FIG. 4) or as long as the reflector 400 (as shown in FIG. 2) or other elements are stably disposed. Besides, in addition to utilizing the screws 340 and 342, it is also allowed to adopt glue joining, lodging, or other methods of fixation to fix the first U-shaped plastic frame 302, the second U-shaped plastic frame 304, and the back cover body 300 in the second and third embodiments.

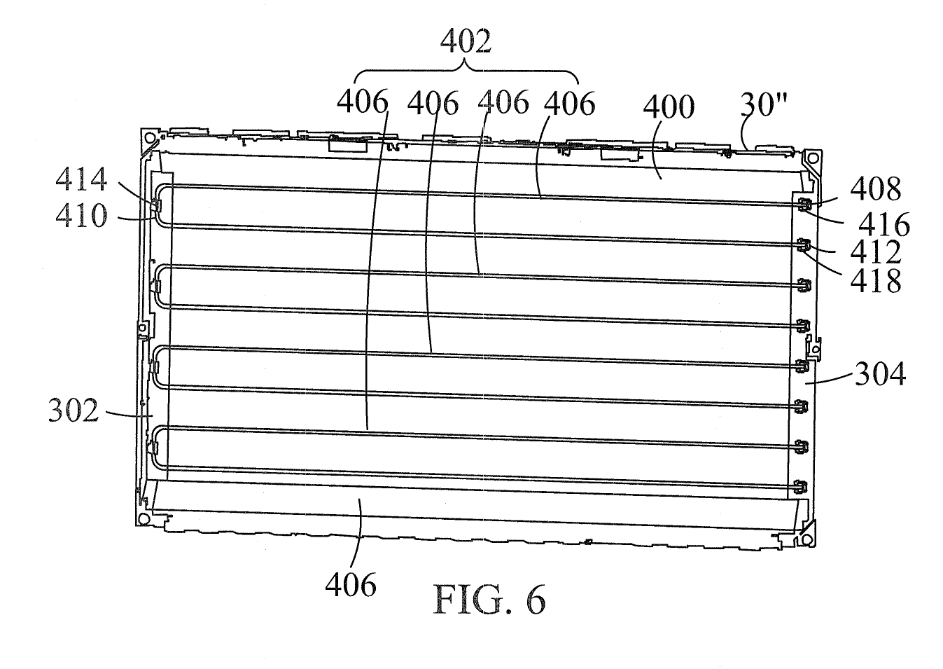

Referring to FIG. 6 illustrating the back cover module 30″ of FIG. 5 (or the back cover module 30′ of FIG. 4 or the back cover module 30 of FIG. 3) where the light source module 402 and the reflector 400 are fixed, the light source module 402 comprises a plurality of U-shaped lamp tubes 406. Each of the U-shaped lamp tubes 406 comprises a first electrode 408, a bottom terminal 410, and a second electrode 412. The first electrode 408 acts as a high-voltage end or a low-voltage end, and the second electrode 412 correspondingly acts as a low-voltage end or a high-voltage end. The first electrode 408 and the second electrode 412 are arranged alternately. Opposite to the first electrode 408 and the second electrode 412, the bottom terminal 410 is positioned at the other side of the U-shaped lamp tube 406.

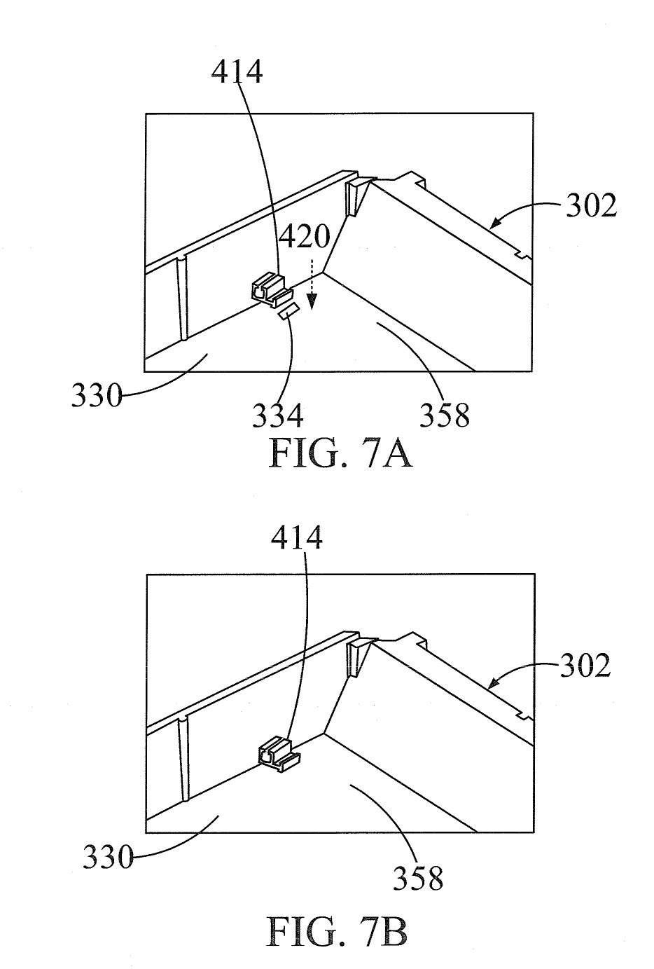

Referring to FIG. 4 or FIG. 5, FIG. 7A, and FIG. 7B, FIGS. 7A and 7B illustrate that a lamp holder 414 of the backlight module 40 (as shown in FIG. 2) is installed onto the first base plate 330 of the first U-shaped plastic frame 302. The first base plate 330, corresponding to the lamp holder 414, comprises a bottom terminal securing hole 334. After the lamp holder 414 is inserted into the bottom terminal securing hole 334 along the direction of the dotted-lined arrow 420, it can be fixed onto the inner surface 358 of the first base plate 330, as shown in FIG. 7B. The bottom terminal 410 of the U-shaped lamp tube 406 shown in FIG. 6 can be fixed onto the inner surface 358 of the first base plate 330 with the lamp holder 414. The lamp holder 414 is homogeneous and is made of insulated rubber and suchlike materials.

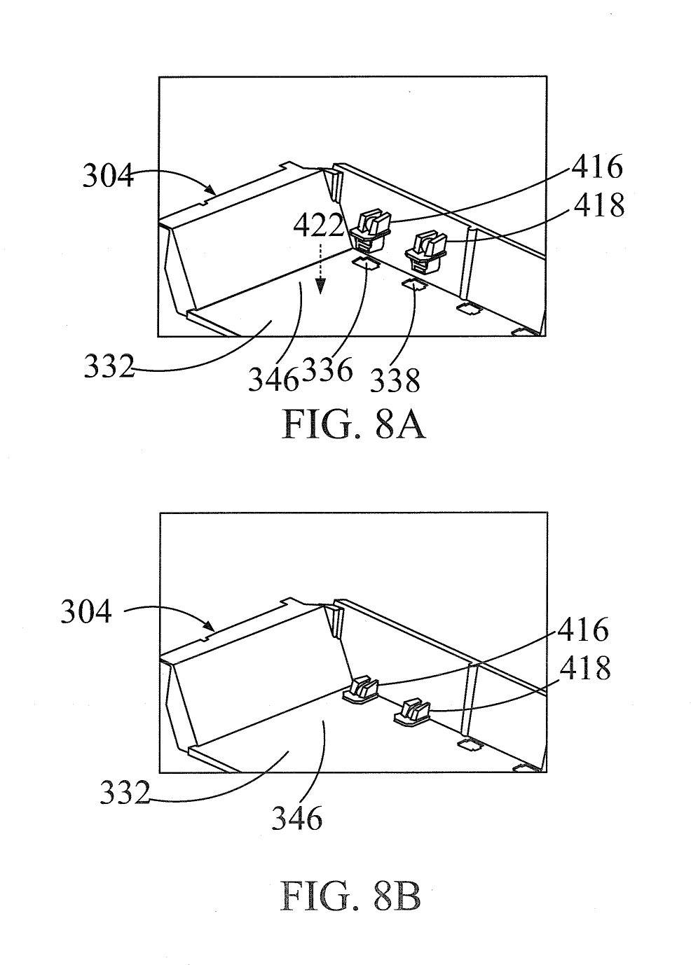

Referring to FIG. 4 or FIG. 5, FIG. 8A, and FIG. 8B, FIGS. 8A and 8B illustrates that a first electrode holder 416 and a second electrode holder 418 of the backlight module 40 (as shown in FIG. 2) are installed onto the second base plate 332 of the second U-shaped plastic frame 304. As shown in FIG. 8A, the second base plate 332, corresponding to the first electrode holder 416 and the second electrode holder 418, respectively comprises a first cavity 336 and a second cavity 338. After the first electrode holder 416 and the second electrode holder 418 are respectively inserted into the first cavity 336 and the second cavity 338 along the direction of the dotted-lined arrow 422, they can be fixed onto the inner surface 346 of the second base plate 332, as shown in FIG. 8B. With the first electrode holder 416 and the second electrode holder 418, the first electrode 408 and the second electrode 412 of the U-shaped lamp tube 406 shown in FIG. 6 can be fixed onto the inner surface 346 of the second base plate 332. Besides, the first electrode holder 416 can be fixed onto the first electrode 408 of the U-shaped lamp tube 406, and the second electrode holder 418 can be fixed onto the second electrode 412 of the U-shaped lamp tube 406. The first electrode holder 416 and the second electrode holder 418 can be taken as connectors. The external material of the connectors is rubber, and the internal material of the connectors comprise conductive materials such as metal.

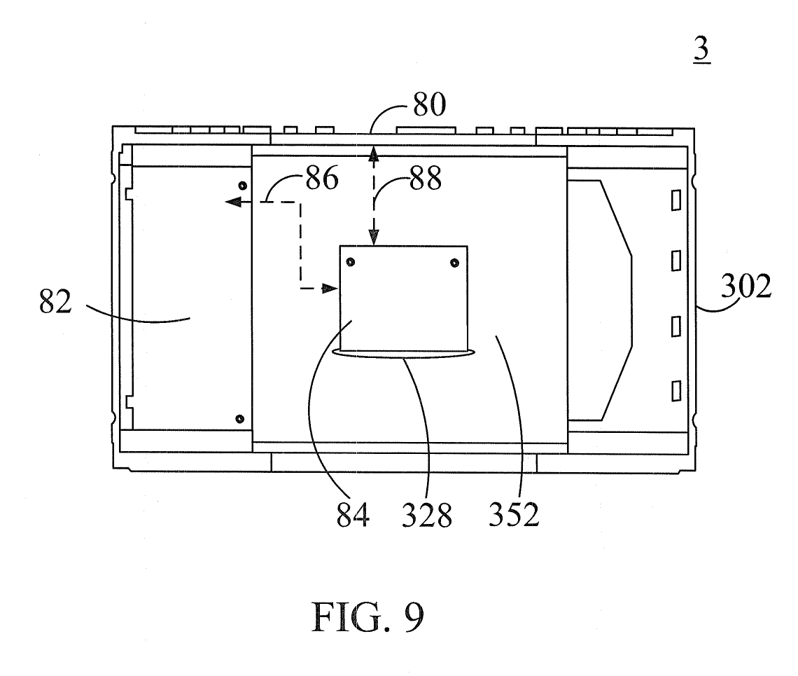

Referring to FIG. 9, PCBs for use in the flat panel display device 3 of the present invention is illustrated. The flat panel display device 3 additionally comprises a source board 80, an LCD integrated power supply board (LIPS board) 82, and a main board 84. The source board 80 drives the display panel 60 (as shown in FIG. 2). The LIPS board 82 supplies power to the display panel 60 or the backlight module 40 (as shown in FIG. 2), and especially to the first electrode 408 and the second electrode 412 of the backlight module 40 (as shown in FIG. 6). The main board 84 controls the display panel 60 (as shown in FIG. 2). The directions of the dotted-lined arrows 86 and 88 represent those of signal transmissions between the source board 80 and the main board 84 and between the LIPS board 82 and the main board 84. The fixed modes of the source board 80, the LIPS board 82, and the main board 84 are described as follows:

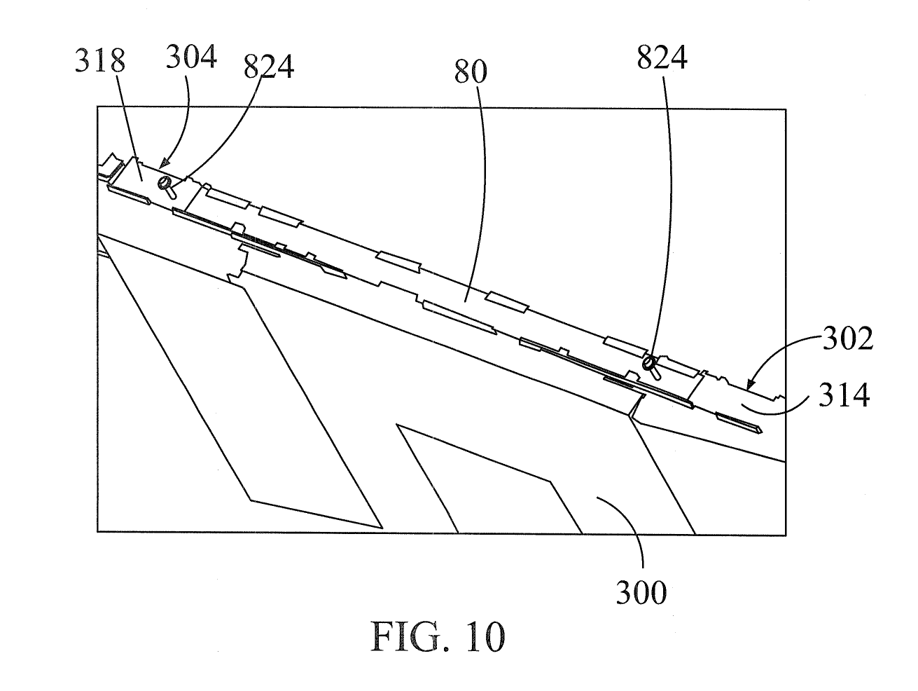

Referring to FIG. 10 illustrating the source board 80 and the back cover body 300, the source board 80 disposed on the back cover body 300 is fixed onto the outer surface of the first sliding track 322 as shown in FIG. 3. Preferably, the source board 80 can be further fixed onto the first end 314 of the first U-shaped plastic frame 302 and/or the third end 318 of the second U-shaped plastic frame 304 with screws 824 or other methods of fixation. In other embodiments, the source board 80 can also be fixed onto the first end 314 and the third end 318 with screws 824 or other methods of fixation while merely touching the first sliding track 322 of the back cover body 300 (as shown in FIG. 3) or being separated from the first sliding track 322 by a gap.

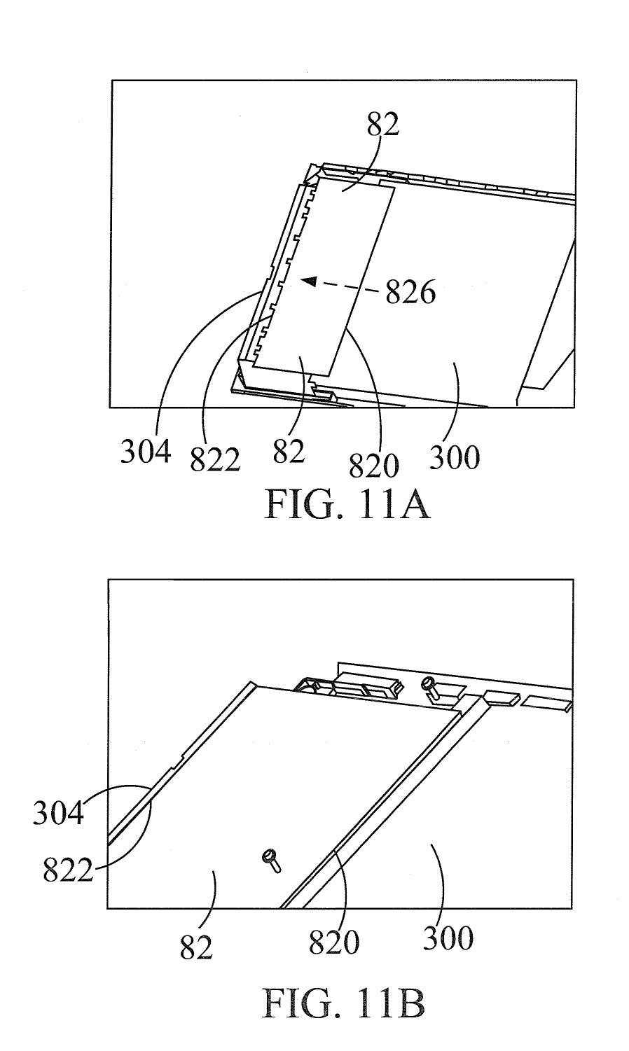

Please refer to FIG. 11A and FIG. 11B. FIG. 11A and FIG. 11B show how to the assemble LIPS board 82 with the back cover body 300. The LIPS board 82 comprises a first lateral edge 820 and a second lateral edge 822. The second lateral edge 822 is fixed onto the second U-shaped plastic frame 304, and the first lateral edge 820 is fixed onto the back cover body 300. In FIG. 11A, the second lateral edge 822 of the LIPS board 82 is inserted into the second U-shaped plastic frame 304 along the direction of the dotted-lined arrow 826. After the second lateral edge 822 is inserted along the direction of the dotted-lined arrow 826, the first lateral edge 820 is fixed onto the back cover body 300 through locking or other methods of fixation. The combined structure thereof is illustrated in FIG. 11B.

Please refer FIG. 3 and FIG. 9. FIG. 3 and FIG. 9 illustrate how to fix the main board 84 with the back cover body 300. In the beginning, the main board 84 is disposed on the bearing plate 328. The main board 84 is fixed onto the outer surface 352 of the back cover body 300. As a result, the main board 84 can be electrically connected to the display panel 60 (as shown in FIG. 2) via the opening 326.

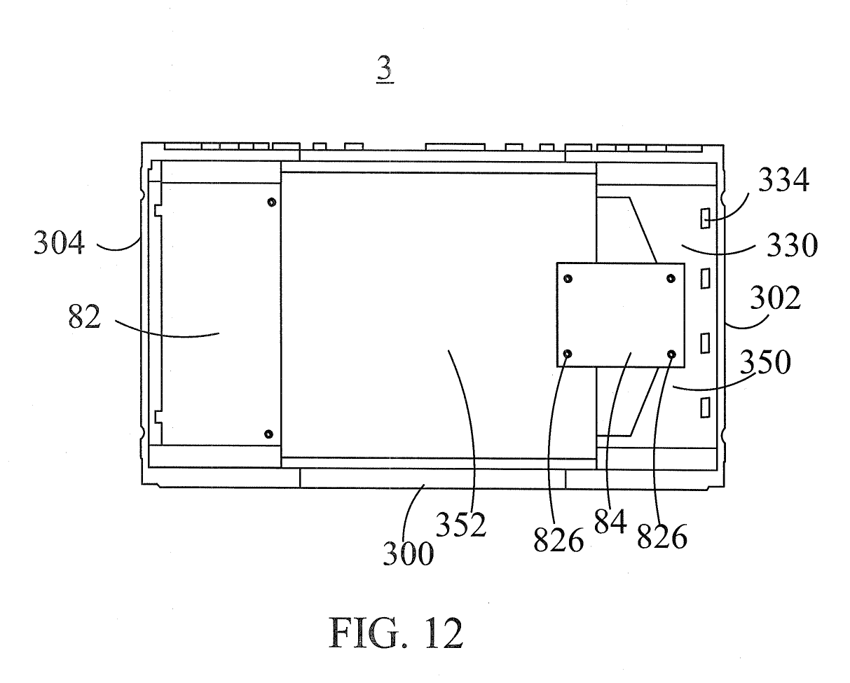

Referring to FIG. 12 illustrating the main board 84 according to another embodiment, the main board 84 is disposed or locked on the outer surface 352 of the back cover body 300 and the outer surface 350 of the first base plate 330 with screws 826. Moreover, the main board 84 can also be fixed with other methods of fixation such as glue joining and lodging.

In the present invention, the substrate module of the back cover module, the backlight module, and the flat panel display device utilizes the back cover body, the first U-shaped plastic frame, and the second U-shaped plastic frame to form a required supporting structure. Thus, the size of the back cover body can be reduced, and the manufacturing costs and the weight of the flat panel display device can be lowered. Furthermore, the back cover body and the system can be designed integrally; for example, the source board, the LCD integrated power supply board (LIPS Board), and the main board are disposed on both sides of the back cover body. As a result, the back cover body can provide the aforementioned printed circuit board (PCB) with good earth connections as well as take the overall strength into consideration.

While the present invention has been described in connection with what is considered the most practical and preferred embodiments, it is understood that this invention is not limited to the disclosed embodiments but is intended to cover various arrangements made without departing from the scope of the broadest interpretation of the append claims.

What is claimed is:

1. A back cover module comprising:
a back cover body comprising a first corner, a second corner, a third corner, and a fourth corner;
a first U-shaped plastic frame comprising a first end fixed on the first corner and a second end fixed on the second corner; and
a second U-shaped plastic frame comprising a third end fixed on the third corner and a fourth end fixed on the fourth corner,
wherein the first U-shaped plastic frame encloses with the back cover body to form a opening space.

2. The back cover module of claim 1, wherein the back cover body comprises a first sliding track, formed between the first corner and the third corner, for accommodating the first end and the third end.

3. The back cover module of claim 1, wherein the back cover body comprises a second sliding track, formed between the second corner and the fourth corner, for accommodating the second end and the fourth end.

4. A backlight module comprising:
a back cover module as claimed in claim 1;
a reflector disposed on an inner surface of the back cover body; and
a light source module disposed on the reflector positioned between the back cover module and the light source module.

5. The backlight module of claim 4, wherein the first U-shaped plastic frame further comprises a first base plate, the second U-shaped plastic frame further comprises a second base plate, and the reflector covers the inner surfaces of the first base plate, the back cover body, and the second base plate.

6. The backlight module of claim 5, wherein the light source module comprises a U-shaped lamp tube having a first electrode, a bottom terminal, and a second electrode.

7. The backlight module of claim 6 further comprising a lamp holder for fixing the bottom terminal of the U-shaped lamp tube on the inner surface of the first base plate.

8. The backlight module of claim 6 further comprising a first electrode holder for fixing the first electrode and a second electrode holder for fixing the second electrode.

9. The backlight module of claim 8, wherein the first electrode holder is used for fixing the first electrode on the inner surface of the second base plate, and the second electrode holder is used for fixing the second electrode on the inner surface of the second base plate.

10. The backlight module of claim 5 further comprising one or more screws for locking the second base plate and the back cover body.

11. A flat panel display device comprising:
a backlight module as claimed in claim 4; and
a display panel disposed on the backlight module, wherein the light source module is positioned between the back cover body and the display panel.

12. The flat panel display device of claim 11 further comprising a source board disposed on the back cover body for driving the display panel.

13. The flat panel display device of claim 12, wherein the source board is fixed on the outer surface of the first sliding track.

14. The flat panel display device of claim 12, wherein the source board is fixed on the first end of the first U-shaped plastic frame or the third end of the second U-shaped plastic frame.

15. The flat panel display device of claim 11 further comprising an integrated power supply board having a first lateral edge fixed with the back cover body and a second lateral edge fixed with the second U-shaped plastic frame, the integrated power supply board is used for supplying power to the display panel or the light source module.

16. The flat panel display device of claim 15, wherein the second lateral edge of the integrated power supply board is engaged with the second U-shaped plastic frame.

17. The flat panel display device of claim 15, wherein the first lateral edge of the integrated power supply board is locked on the back cover body.

18. The flat panel display device of claim 11, wherein the back cover body further comprises an opening and a bearing plate protruded out of the outer surface of the back cover body and connected to a fringe of the opening.

19. The flat panel display device of claim 18 further comprising a main board disposed on the bearing plate and electrically connected to the display panel via the opening, for controlling the display panel.

20. The flat panel display device of claim 19, wherein the main board is fixed on outer surface near the opening.
